(19) United States
(12) Patent Application Publication
(10) Pub. No.: US 2009/0310293 A1
(43) Pub. Date: Dec. 17, 2009

(54) QUICK-DETACHABLE MOUNTING SYSTEM

(75) Inventors: Ping-Ho Cheng, Jhonghe City (TW); Chia-Yen Hsu, Hsin Chuang City (TW); Miao-Tzu Chou, San-Hsia Town (TW)

Correspondence Address: DATAVAN INTERNATIONAL CORP., P.O. BOX 108-00403, TAIPEI, TW

(73) Assignee: DATAVAN INTERNATIONAL CORP., Jhonghe City (TW)

(21) Appl. No.: 12/137,558

(22) Filed: Jun. 12, 2008

(51) Int. Cl. H05K 7/00

(52) U.S. Cl. 361/679.33

(57) ABSTRACT

A quick-detachable mounting system of an electronic equipment is disclosed to include a host, which has locating holes and hook holes on the bottom side, a base unit, which has upright locating rods respectively upwardly extending from the top side and respectively insertable into the locating holes of the host and two hooks that are respectively formed of a part of the two opposite vertical side panels and respectively automatically forced into engagement with the hook holes of the host after insertion of the locating rods into the respective locating holes, and a connecting member, which is set between the host and the base unit and has through holes and openings for the passing of the locating rods and the hooks of the base unit and two upright lugs respectively inserted into respective bottom through holes of the host.

### BACKGROUND OF THE INVENTION

1. Field of the Invention

The present invention relates to the mounting/dismounting arrangement of an electronic equipment and more particularly, to a quick-detachable mounting system of an electronic equipment that allows quick mounting/dismounting of the electronic equipment without tools, facilitating maintenance and cleaning works

2. Description of the Related Art

Following fast development of modern technology and its application, the distance between people has been greatly shortened. Nowadays, KIOSK information systems are commonly seen in public places. An interactive KIOSK is a self-service device that provides an informational public service or serves a commercial purpose. Self-service kiosks are being intensively used in a variety of applications, including information directories, customer self-service terminals, electronic catalogs, internet access terminals, tourism guides and more. For the advantages of small space occupation and wide variety of services, kiosk provides an easy to use virtual store.

Following development kiosk content management software and kiosk related technology, kiosk services are not limited to window browser, talent agency for virtual characters and gateway to solutions. 3G technology has now been incorporated into kiosk services. Nowadays, kiosk services enter internet shopping, information download, tickets vending, prepaid card/virtual money selling and monetary value storing, digital photo editing and transmission, and assigned printing. A kiosk system may function as a virtual store. This non-serviceman and self-checkout management brings convenience to consumers and helps businessmen to expand selling channels. There is still a great potential market for kiosk business.

A typical self-service device generally comprises three parts, namely, the host, the display device, and the base. The base accommodates a computer peripheral apparatus, such as mouse, keyboard, scanner or printer. The printer of a self-service device can be assigned to print digital images, pictures, or letters, and then directly provided to people. These self-service devices save staff and employees' wage and welfare and bring convenience to people.

FIGS. 7 and 8, illustrates the mounting arrangement of a self-service device. According to this design, the computer peripheral apparatus is mounted in the base B below the host A. When the computer peripheral apparatus failed, the worker must use a screwdriver to remove the screws C from the base B and the host A, and then separate the host A from the base B, and then perform troubleshooting and repair work. Further, the computer peripheral apparatus tends to be covered with dust after a long use of the self-service device. If the computer peripheral apparatus is a printer, the printing face of the printer will be covered with dust after a long use of the self-service device, resulting in a poor printing quality. Therefore, the computer peripheral apparatus of a self-service device must be regularly cleaned. When wishing to clean the computer peripheral apparatus, the worker must unfasten the screws and then separate the host A from the base B so that the cleaning and maintenance work can be performed. This screw-based mounting design wastes much labor in cleaning and maintenance work. During mounting or dismounting of the system, the screws may be missed accidentally. Further, any screw size error will complicate the installation.

Therefore, it is desirable to provide a mounting system for self-service device that eliminates the aforesaid problems.

### SUMMARY OF THE INVENTION

The present invention has been accomplished under the circumstances in view. It is the main object of the present invention to provide a quick-detachable mounting system for self-service device, which allows quick mounting and dismounting of the system without any tools.

To achieve this and other objects of the present invention, the quick-detachable mounting system comprises a host and a base unit. The host comprises an accommodation chamber, which accommodates a media storage device, a front side mounted with a media player, and a plurality of locating holes and hook holes in the bottom side. The base unit comprises a plurality of upright locating rods respectively upwardly extending from the top side thereof and respectively insertable into the locating holes of the host, two vertical crevices formed in each vertical side panel and extending to the top side of the respective vertical side panel, and a hook formed integral with each vertical side panel and suspending between the vertical crevices on the respective vertical side panel for hooking in the hook holes of the host upon insertion of the upright locating rods of the base unit into respective locating holes of the host.

The quick-detachable mounting system further comprises a rectangular connecting member set between the host and the base unit. The rectangular connecting member comprises a plurality of through holes for the passing of the locating rods of the base unit, two openings symmetrically disposed near two opposite short sides thereof for the passing of the hooks of the base unit, and two upright lugs respectively upwardly extending from the outer side of each openings. Further, the host comprises two through holes formed on the bottom side for receiving the upright lugs of the rectangular connecting member respectively.

### BRIEF DESCRIPTION OF THE DRAWINGS

FIG. 1 is an elevational view of a quick-detachable mounting system in accordance with the present invention.

FIG. 2 is an exploded view of the quick-detachable mounting system according to the present invention.

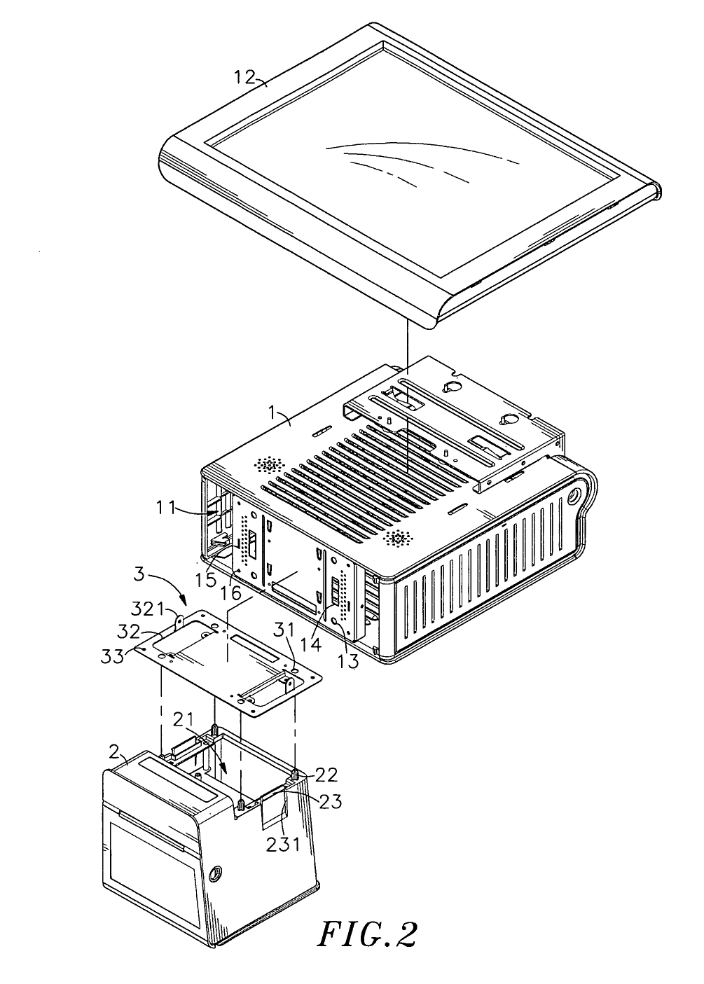

FIG. 3 is an enlarged view of a part of FIG. 2.

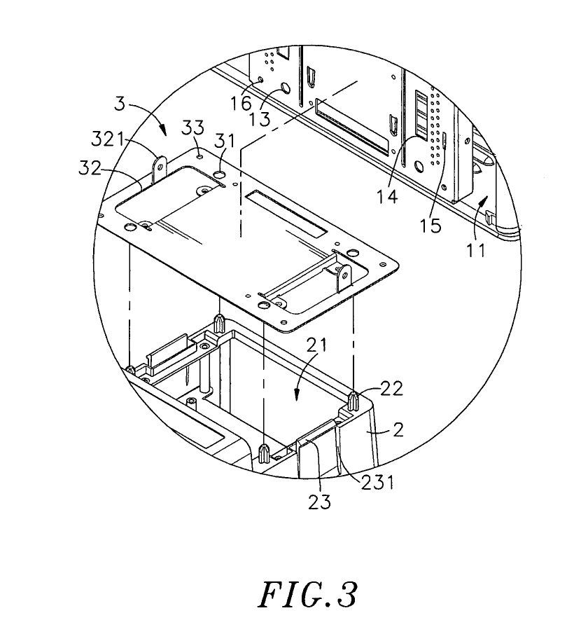

FIG. 4 is a schematic sectional side view showing the installation procedure of the present invention (I).

FIG. 5 is a schematic sectional side view showing the installation procedure of the present invention (II).

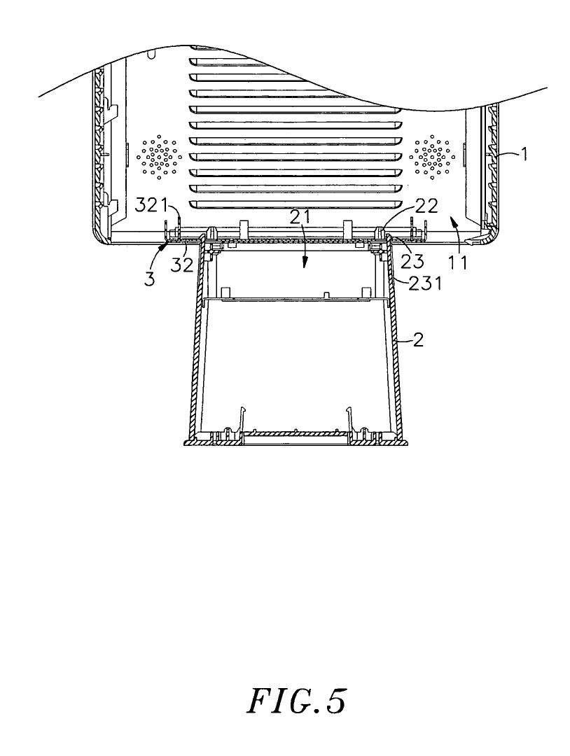

FIG. 6 is a schematic sectional side view showing the installation procedure of the present invention (III).

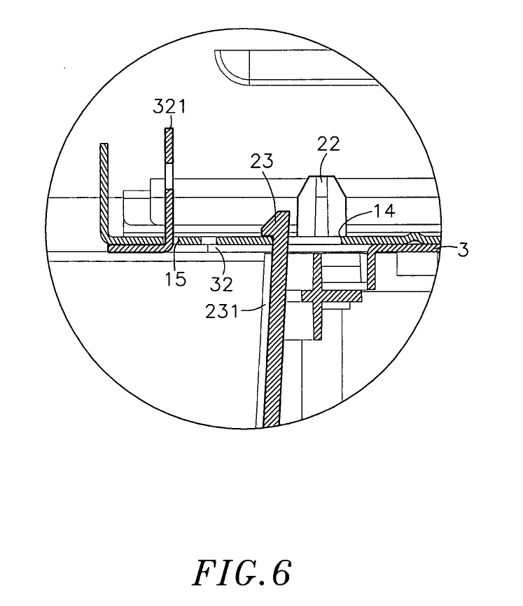

FIG. 7 is an exploded view of a conventional self-service device.

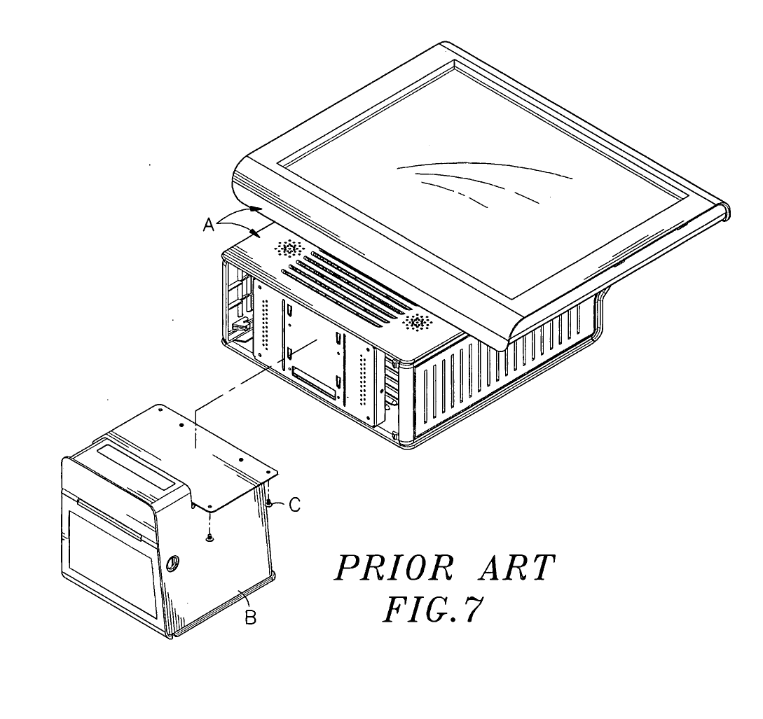

FIG. 8 is an elevational assembly view of a part of the self-service device shown in FIG. 7.

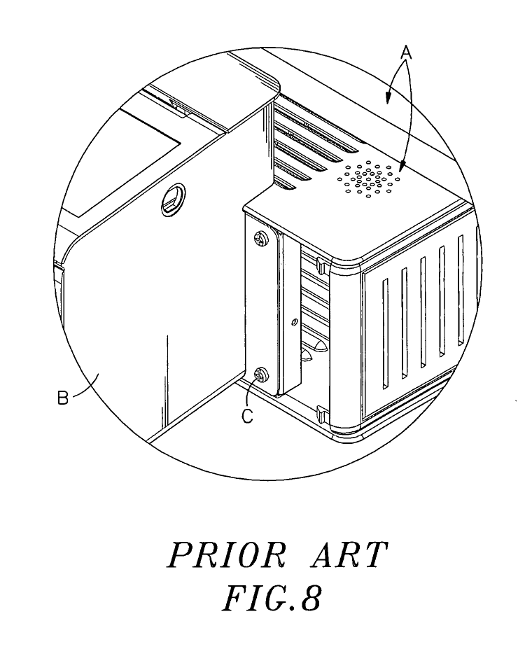

### DETAILED DESCRIPTION OF THE PREFERRED EMBODIMENT

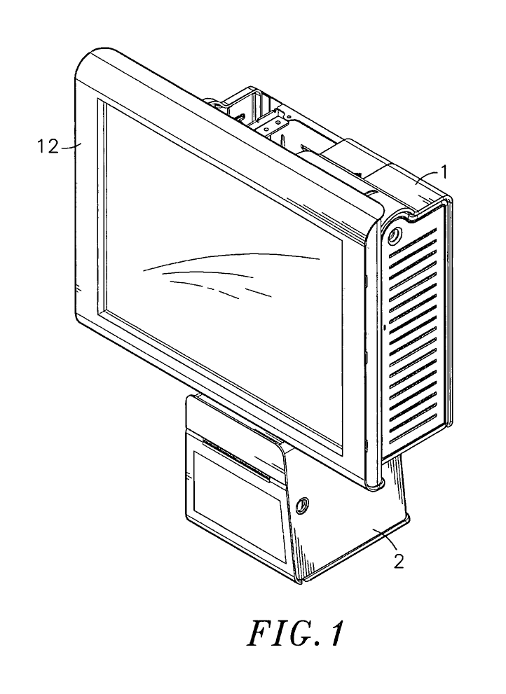

Referring to FIGS. 1˜3, a quick-detachable mounting system in accordance with the present invention is shown comprising a host 1, a base unit 2 and a connecting member 3.

The host 1 defines therein an accommodation chamber 11 for the accommodation of media storage means (not shown), having a media player 12 provided at the front side thereof. The host 1 has a plurality of locating holes 13 on the bottom wall thereof, hook holes 14 formed on the bottom wall and symmetrically disposed at two opposite lateral sides, two through holes 15 cut through the bottom wall and respectively disposed adjacent to the hook holes 14 at an outer side, and a plurality of mounting holes 16 respectively formed in the four corners of the bottom wall.

The base unit 2 defines therein an accommodation chamber 21 for the accommodation of a computer peripheral apparatus (not shown). The base unit 2 has a plurality of upright locating rods 22 disposed at the top side thereof corresponding to the locating holes 13 of the host 1, two hooks 23 symmetrically disposed at two opposite lateral sides corresponding to the hook holes 14. The two hooks 23 are respectively formed integral with the two opposite vertical side panels of the base unit 2. The two hooks 23 are made by means of making two sets of vertical crevices 231 on the two opposite vertical side panels of the base unit 2.

The connecting member 3 is a rectangular plate member, having a plurality of through holes 31 for the passing of the upright locating rods 22 of the base unit 2, two openings 32 symmetrically disposed near the two opposite short sides for the passing of the two hooks 23 of the base unit 2 to hook in the respective hook holes 14 of the host 1, two upright lugs 321 respectively upwardly extending from the outer side of each of the opening 32, and a plurality of positioning holes 33 respectively disposed in the four corners for the mounting of fastening elements to fixedly secure the connecting member 3 to the mounting holes 16 of the host 1.

The media storage means to be accommodated in the accommodation chamber 11 of the host 1 can be a floppy disk drive, hard disk drive, DVD player or the like that has storage interface electrically connectable to the media player 12. The media player 12 functions as an interactive interface for media database access and output of multimedia information such as digital images, pictures, letters and/or music. The media player 12 can be a speaker, projector, TV, LCD monitor or touch screen. Further, the computer peripheral apparatus to be accommodated in the accommodation chamber 21 of the base unit 2 can be a mouse, keyboard, scanner, printer, etc. When the computer peripheral apparatus accommodated in the base unit 2, the media storage means accommodated in the host 1 and the media player 12 are electrically connected together, the system works a self-service device. Because the function of this self-service device is not within the scope of the claims of the present invention, no further detailed description in this regard is certainly necessary.

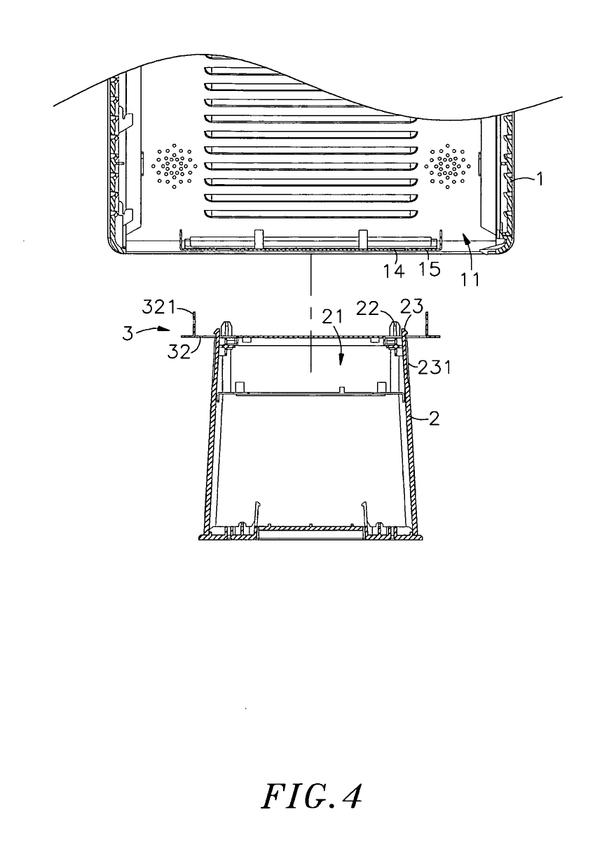

Referring to FIGS. 4˜6, during installation, the upright locating rods 22 of the base unit 2 are respectively inserted through the through holes 31 of the connection member 3 into the locating holes 13 of the host 1, and at the same time, the two hooks 23 are respectively inserted through the openings 32 of the connection member 3 and hooked in the hook holes 14 of the host 1.

Further, the upright lugs 321 of the connection member 3 are respectively inserted through the through holes 15 of the host 1, and fastening elements (not shown) are respectively inserted through the positioning holes 33 of the connection member 3 and fastened to the mounting holes 16 of the host 1 to fixedly secure the connection member 3 to the host 1.

The computer peripheral apparatus accommodated in the base unit 2 may be covered with dust and stain after a long use of the self-service device. If the computer peripheral apparatus is a printer, contamination of the printing face will result in a poor printing quality. Accumulation of dust in the computer peripheral apparatus may affect normal functioning of the computer peripheral apparatus. In this case, a cleaning work is necessary.

Before cleaning the self-service device, the base unit 2 must be detached from the host 1 by means of: pushing the two hooks 23 inwards toward each other to disengage the hooks 23 from the hook holes 14 and then moving the host 1 vertically upwards relative to the base unit 2 to disconnect the locating holes 13 from the locating rods 22 of the base unit 2. After removal of the host 1 from the base unit 2, the inside of the base unit 2 can then be well cleaned.

Further, if the computer peripheral apparatus failed or damaged, the base unit 2 can easily be detached from the host 1 by hand without any tools. After the repair work, the base unit 2 is fastened to the main init 1 again.

In general, the invention provides a quick-detachable mounting system, which has the following features and advantages:

1. The locating holes 13 and hook holes 14 of the host 1 are arranged so that the locating rods 22 and the hooks 23 of the base unit 2 are respectively hooked in the locating holes 13 and the hook holes 14 to secure the base unit 2 to the host 1 firmly.

2. The hooks 23 are respectively formed integral with the two opposite vertical side panels of the base unit 2. Each hook 23 has two opposite lateral sides separated from the associating vertical side panel of the base unit 2 by the crevice 231. Therefore, the hooks 23 are springy, and can be temporarily curved inwards toward each other and disengaged from the hook holes 14 of the host 1 for allowing disconnection of the locating rods 22 from the locating holes 13 of the host 1 by means of moving the host 1 vertically upwardly away from the base unit 2.

3. The user can rapidly fasten the host 1 and the base unit 2 together or dismount the host 1 and the base unit 2 by hand without any tools. Therefore, cleaning and maintenance works of the system are easy. This design allows easy change or replacement of the computer peripheral apparatus that is accommodated in the base unit 2.

4. The through holes 15 of the host 1 are respectively disposed adjacent to the hook holes 14 for receiving the upright lugs 321 of the connection member 3 so that the positioning holes 33 of the connection member 3 can be fastened to the mounting holes 16 of the host 1 directly with fastening elements.

Although a particular embodiment of the invention has been described in detail for purposes of illustration, various modifications and enhancements may be made without departing from the spirit and scope of the invention.

What the invention claimed is:

1. A quick-detachable mounting system comprising:
a host, said host comprising an accommodation chamber, which accommodates a media storage device, a front side mounted with a media player, and a plurality of locating holes and hook holes in a bottom side thereof; and
a base unit, said base unit comprising a plurality of upright locating rods respectively upwardly extending from a top side thereof and respectively insertable into said locating holes of said host, two vertical crevices formed in each vertical side panel and extending to the top side of the respective vertical side panel, and a hook formed integral with each said vertical side panel and suspending between said vertical crevices on the respective vertical side panel for hooking in said hook holes of said host.

2. The quick-detachable mounting system as claimed in claim 1, further comprising a rectangular connecting member set between said host and said base unit, said rectangular connecting member comprising a plurality of through holes for the passing of said locating rods of said base unit, and two openings symmetrically disposed near two opposite short sides thereof for the passing of said hooks of said base unit.

3. The quick-detachable mounting system as claimed in claim 2, wherein said rectangular connecting member comprises two upright lugs respectively upwardly extending from an outer side of each of said openings; said host further comprises two through holes formed on the bottom side thereof for receiving said upright lugs of said rectangular connecting member respectively.

4. The quick-detachable mounting system as claimed in claim 1, wherein said media storage device comprises an interactive interface electrically connected with said media player for output of multimedia information through said media player.

5. The quick-detachable mounting system as claimed in claim 1, wherein said media storage device is selected from the group of floppy disk drive, hard disk drive and DVD player.

6. The quick-detachable mounting system as claimed in claim 4, wherein said media player is selected from the group of speaker, projector, TV, LCD monitor and touch screen.

7. The quick-detachable mounting system as claimed in claim 1, wherein said base unit comprises an accommodation chamber and a computer peripheral apparatus accommodated in said accommodation chamber of said base unit and electrically connected to said media storage device, said computer peripheral apparatus being selected from the group of mouse, keyboard, scanner and printer.
